(19) United States
(12) Patent Application Publication
(10) Pub. No.: US 2017/0064860 A1
(43) Pub. Date: Mar. 2, 2017

(54) Method and System for Automatic Location Tracking of Information Technology Components in a Data Center

(71) Applicant: Avocent Corporation, Huntsville, AL (US)

(72) Inventors: Carlos Martins, Freemont, CA (US); Nei Chiaradia, Pleasanton, CA (US); Arnaldo Zimmermann, Fremont, CA (US)

(21) Appl. No.: 15/351,198

(22) Filed: Nov. 14, 2016

Related U.S. Application Data
(63) Continuation of application No. 12/546,498, filed on Aug. 24, 2009.

(51) Int. Cl. H05K 7/14; H04B 5/00

(52) U.S. Cl. CPC H05K 7/1498; H04B 5/0062

(57) ABSTRACT

Methods and systems provide the automatic tracking of the physical location of information technology components in a data center. These systems automatically identify where a given IT component, such as a server, router, switch or other device, is located. They automatically identify which slot the IT component is located in a given rack in the data center. When a server is added or removed from a particular slot, the tracking database is automatically notified and updated, and users of the database have instantaneously accurate information about the location of each IT component in a data center. If the server is changed to a different slot or rack, the system immediately identifies that the given server or device is located in a different location. Users can rely on the information in the database when remotely managing the data center's IT assets.

### RELATED APPLICATION

This patent application is related to U.S. patent application Ser. No. ______, entitled “Method and System for Automatic Tracking of Information Technology Components and Corresponding Power Outlets in a Data Center” which is incorporated herein by reference.

### FIELD OF THE INVENTION

This generally relates to information technology components in a data center, and more particularly to automatic location tracking of information technology components, such as servers, routers and switches, in a data center.

### BACKGROUND

Data centers are buildings or rooms that house large numbers of information technology components such as servers, data processors, switches, routers, network equipment or other computer components. Typically, the interior of a data center is filled with multiple rows of cabinet-like equipment called racks that are arranged in parallel to one another throughout the data center. Each rack houses multiple, vertically spaced components, and an aisle for service personnel is often provided between rows of racks. In this way, a large number of servers or other components can be placed in a data center.

The individual information technology (IT) components mounted inside the racks are supplied power by power distribution units (PDU) that typically mount to the rear columns of the rack. A standard rack typically includes front-mounting rails to which multiple units of equipment, such as servers and CPUs, are mounted and stacked vertically within the rack. The components stacked in a rack are each housed in a slot, and a rack may have many slots. A standard rack at any given time can be sparsely or densely populated with a variety of different IT components. Also, a single IT component may occupy more than one slot.

When tracking these IT components, data center technicians need to be sure of the existence and location of them. Sometimes during maintenance, data center technicians can add, change or remove an IT component, or move the component elsewhere within the data center. In these cases, if the database for tracking the location of these components is not updated, conventionally a manual process, the database will be outdated and contain inaccurate information. A technician's reliance on this incorrect information can be greatly detrimental. For example, if a technician desires to locate a particular target component, the component may not be where the database indicates it is, or may not be part of the data center anymore. When planning a data center, the placement of components in various slots on racks throughout the data center takes careful planning and consideration of various factors such as power supply, ventilation, heating and cooling. These factors may change from time to time. For example, it may be desirable to move components in a rack due to a change in power conditions.

Many organizations use enterprise asset management solutions to help manage their valuable IT assets, but find that updating asset information, such as their physical location, still requires extensive manual effort. If an IT component is not properly accounted for, it is no longer visible, and increases the risk of underutilization of the component, or it being lost or stolen.

Conventional systems address physical asset management at the data center room level, or rely heavily on manual processes and periodic manual audits for information updates regarding the physical location of these components in the data center. Manual audits are an expensive and time-consuming process. These systems do not give the users an automatic, instantaneous and cost effective way of knowing where a given IT component is located at any point in time within the data center. They do not provide a way for users to automatically have up-to-date physical location information for where an IT component is within a given data center room, on which rack they it resides, or in which slot within a rack.

Any changes in the infrastructure such as removing or changing the location of an IT component are not detected immediately by conventional systems. In these systems, technicians are relied upon to notify the changes through proper communications, and a person manually updates the database. These processes are often violated through human error, leaving the database with incorrect information. As a result, conventional systems do not allow users to be sure that when remotely managing location information of a given server or device the right server or device will be managed.

Accordingly, there is a desire to address problems associated with of the management of location information of the physical location of IT components in a data center. It is desirable to have methods and systems to avoid these and other related problems.

### SUMMARY

In accordance with methods and systems consistent with the present invention, a method in a data processing system is provided for automatically tracking locations of IT components in a data center comprising inserting one or more IT components in one or more slots in one or more racks in the data center, and automatically identifying the one or more IT components in the one or more slots in the one or more racks. The method further comprises automatically identifying the one or more slots in which the one or more IT components are inserted, and automatically identifying when one or more of the IT components are removed from one or more of the slots in one or more of the racks.

In accordance with an implementation, a method in a data processing system is provided for automatically tracking locations of IT components in a data center comprising inserting one or more IT components in one or more slots in a rack in the data center, and automatically identifying the one or more IT components inserted into the one or more slots in the rack.

In another implementation, a data processing system is provided for automatically tracking locations of IT components in a data center comprising a rack comprising a slot configured to store an IT component comprising an RFID tag uniquely identifying the IT component. The slot configured to store an IT component further comprises an antenna configured to receive a signal from the RFID tag indicating an identification of the IT component, and an RFID reader configured to receive the signal from the antenna, process the signal, and send the identification to a module configured to send the identification to a database. The database is configured to store identification and location information of IT components in the data center, and to update upon receipt of the identification from the module.

In yet another implementation, a method in a data processing system is provided for automatically tracking locations of IT components in a data center comprising inserting one or more IT components in one or more racks in the data center, and automatically identifying the one or more IT components in the one or more slots in one or more of the racks. The method further comprises automatically identifying the one or more racks in which the one or more IT components are inserted, and automatically identifying when one or more of the IT components are removed from one or more of the racks.

### BRIEF DESCRIPTION OF THE DRAWINGS

FIG. 1 illustrates an exemplary data center having a rack with several slots containing servers in accordance methods and systems consistent with the present invention.

FIG. 2 illustrates several slots of a rack including servers and modules in accordance with methods and systems consistent with the present invention.

FIG. 3 illustrates a more detailed view of an exemplary module for a rack in accordance with methods and systems consistent with the present invention.

FIG. 4 illustrates steps in an exemplary method in accordance with systems consistent with the present invention.

### DETAILED DESCRIPTION

Methods and systems in accordance with the present invention provide the automatic tracking and management of the physical location of information technology components in a data center. These methods and systems automatically identify where a given IT component, such as a server, router, switch or other device, is located. In particular, they automatically identify which slot the IT component is located in a given rack in the data center. When a server, for example, is added or removed from a particular slot, the tracking database is automatically notified and updated, and users of the database have instantaneously accurate information about the location of each IT component in a data center. If the server is changed to a different slot or rack, the system immediately identifies that the given server or device is located in a different location. Users can confidently rely on the information in the database when remotely managing the data center's IT assets. These systems allow users to be sure that, when remotely managing a given server or device, the physical location of the server or device will be known down to the slot level. This also avoids the need for costly manual audits of IT components in a data center.

Methods and systems in accordance with the present invention provide a hardware and software system using radio-frequency identification (RFID) technology that provides rack and slot-level resolution to automatically identify the location of a given IT component in a rack. The identification of the connected IT components is performed using RFID. RFID involves the use of a device, typically referred to as an RFID tag, applied to or incorporated into a product for identification and tracking using radio waves. Typical RFID tags contain at least two primary parts. One is an integrated circuit for storing and processing information, modulating and demodulating a radio-frequency (RF) signal, and other specialized functions. The second is an antenna for receiving and transmitting the signal. There are generally two types of RFID tags: active RFID tags, which contain a battery and can transmit signals autonomously, and passive RFID tags, which have no battery and use an external source to provoke signal transmission.

In one implementation, insertion and removal of an IT component is automatically detected and communicated to a database responsible for IT component location management. The system further includes small antennas and RFID readers placed in the rack, one in each slot, and passive RFID tags placed in each IT component to be inserted in the rack. Each RFID tag has a unique ID of the IT component, and that information is stored in a database prior to usage of the IT component in the data center. As described further below, the system receives a unique ID from the server, for example, and automatically supplies this information to the database. During maintenance, a technician could add or remove the server's change it to another slot of the rack or a different rack, and the system would receive the identification information, and pass the information upstream to a software layer and then to the database to be updated.

The IT components in a rack each include RFID tags, and each slot in a rack includes a small antenna and RFID reader that reads the RFID tags. Each antenna and RFID reader of a rack receive and read the corresponding RFID tag information for the component in the slot associated with the antenna, and sends the RFID tag information to a module that receives and processes the information. A rack may have several modules that feed information into a master module that relays the information to the database through a software layer.

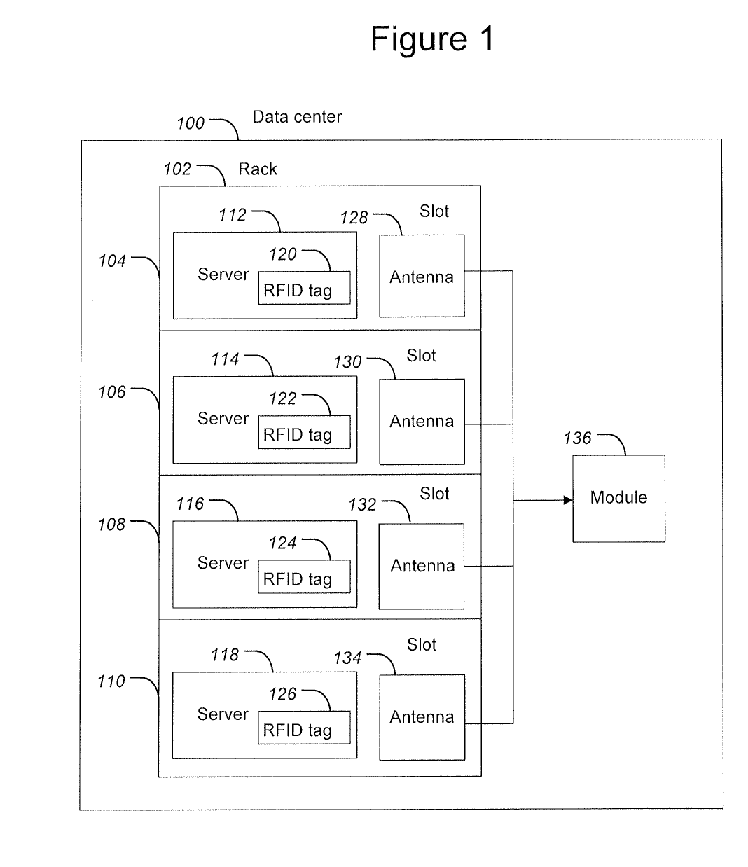

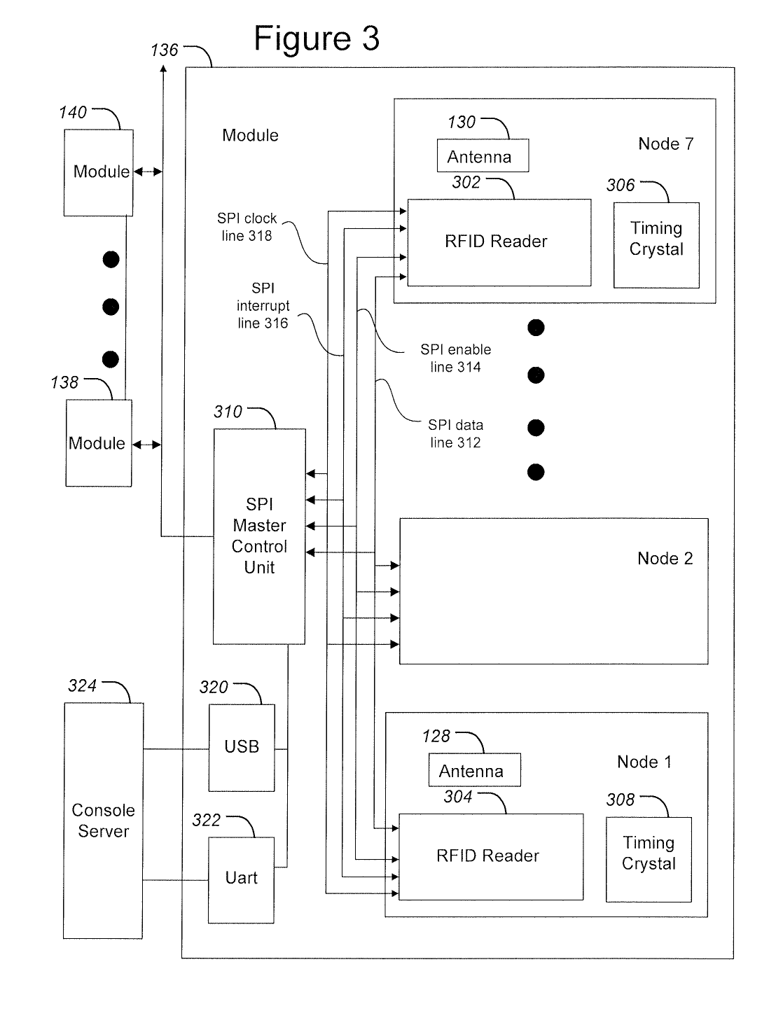

FIG. 1 illustrates an exemplary data center having a rack with several slots containing servers in accordance methods and systems consistent with the present invention. As shown, the data center 100 includes a rack 102 which includes 4 slots 104-110. A data center 100 may have many more racks than shown, and a rack 102 may have many more slots than shown. Each slot 104-110 includes an IT component, such as a server 112. Each server 112-118 includes an RFID tag 120-126 uniquely identifying the server. Each slot 104-110 has a small antenna 128-134 that may receive the identification of the server 112 from the RFID tag of the server in the slot. Each slot has an RFID reader (shown in FIG. 3) associated with the antenna. In one implementation, the antennas 128-134 are placed close to the RFID tags 112-118, so that each antenna may read just its corresponding RFID tag without interference or confusion. The antennas 128-134 and RFID readers receive the identification of the servers 112-118 and send the identification information to the module 136 to be processed and relayed to the database (not shown) that tracks the information for the location of IT components in the data center 100. The module 136 relays to the database the identification of the server as well as the information of which slot and which rack in which the server is located.

In one implementation, the module 136 connects to the database through an intermediate software layer. This software layer may include data center management software, such as DSView from Avocent, Inc, which may allow access to various IT components and provide remote management and remote configuration. The module 136 may be connected to the DSView application through a network, or may be plugged into another appliance (e.g., via the serial port of an Avocent console server or KVM system) which is connected to the DSView through the network. The DSView may pass the information received from the module 136 to the database or other application that manages the IT components of the data center. Other implementations are possible.

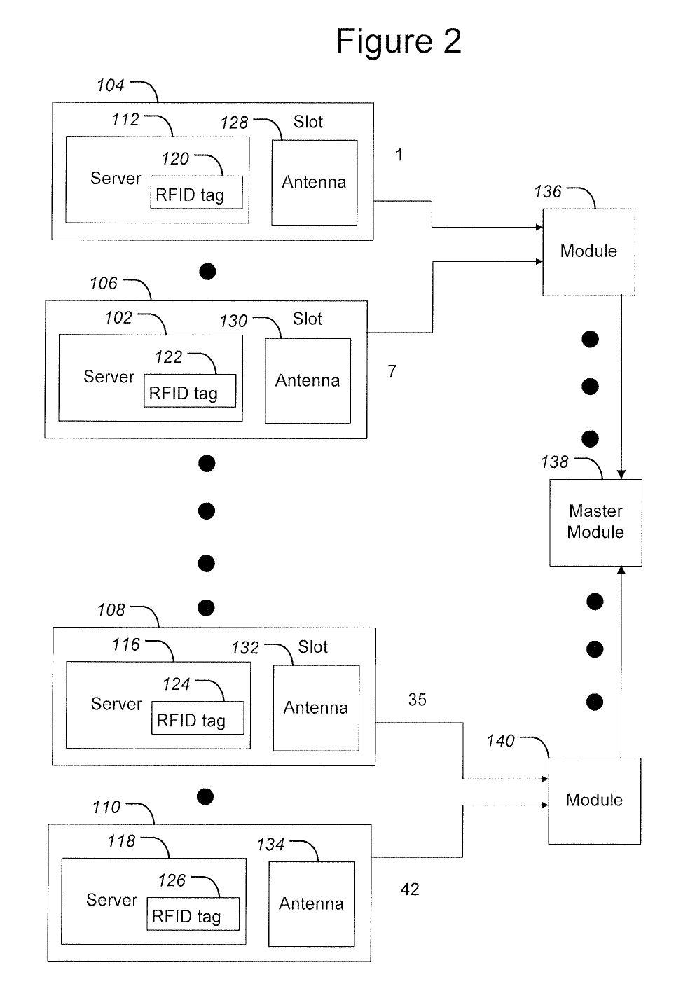

FIG. 2 illustrates several slots of a rack including servers 112-118 and modules 136-140 in accordance with methods and systems consistent with the present invention. In one implementation, a rack may have up to 42 slots. In this implementation, a module 136 receives information from 7 antennas corresponding to 7 slots. Although the figure shows 4 slots 104-110, there are 42 intended to be represented. As such, there are 6 modules 136-140 (not all shown) corresponding to 7 slots and antennas each, including one master module 138. When the modules 136-140 receive the identification information from the antennas 128-134, they relay the information to the master module 138, which in turn relays the information for the entire rack to the software layer and then to the database.

FIG. 3 illustrates a more detailed view of an exemplary module 136 for a rack in accordance with methods and systems consistent with the present invention. As shown on the figure, in one implementation, the module 136 includes seven nodes (not all nodes are shown), each node corresponding to a slot. The node for a slot includes an antenna 128 to receive the signal from the RFID tag included on an IT component in the slot, an RFID reader 304 to process the received RFID tag information, and a timing crystal 308 to control the timing of the operation of the RFID reader 304.

The SPI (Serial Peripheral Interface) master control unit (MCU) 310 is the central control unit and central point of intelligence for the module. It may be a microcontroller and may include firmware. The MCU 310 controls the flow of data throughout the module 136, and the flow of data externally between other modules 138-140 and the console server 324. It communicates with other MCU's in other modules 138-140, and communicates internally with the nodes on a bus. Data flows between the nodes and the MCU 310 on the SPI data line 312. The SPI enable line 314 acts as a chip selector, and activates a particular RFID reader 302. It may denote that the MCU 310 is communicating only with a particular RFID reader 302 and node, e.g., node 7, disabling communication with the other nodes. The interrupt line 316 notifies the nodes of particular events, such as a notification of having information read to communicate to the node, and the SPI clock line 318 controls the timing of the various nodes.

As mentioned previously, the module 138 may notify that database by passing the collected information to a hardware and software appliance, such as a console server 324 or KVM system from Avocent, Inc., or a power distribution unit (PDU), which is connected to a software layer which connects to the database. In one implementation, this information is passed by the master module 138 after collecting the information from the other modules on the rack 102. The module 138 passes the information through a serial port 322, e.g., RS232 (Uart), or USB port 320. The console server 324 processes the data to be sent to the software layer which sends it to the database.

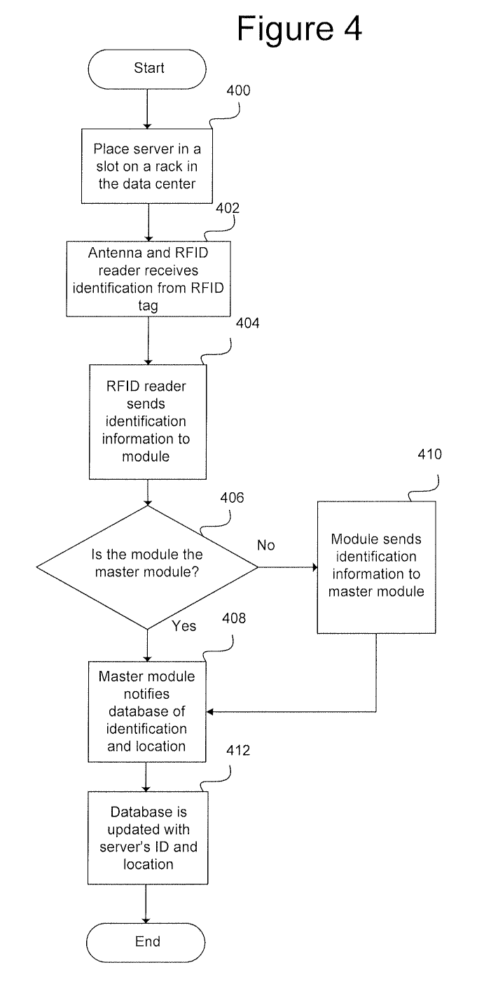

FIG. 4 illustrates steps in an exemplary method in accordance with systems consistent with the present invention. First, an IT component, for example a server 112, having an RFID tag 120 is plugged into a slot 104 in a rack 102 in the data center 100 (step 400). Then, the slot's antenna 128 and RFID reader 302 receive and read the signal from the RFID tag 120 identifying the server 112 to which it is attached (step 402). In one implementation, the RFID tag 120 is a passive tag, and is placed close to the power outlet on the RFID reader 302. In other implementations, the RFID tag 120 may be an active tag. The RFID reader 302 then sends the identification to the MCU 310 of the module 136 with which it is associated (step 404). In one implementation, the master module 138 may send an enable signal enabling the node for the slot 104 in which the antenna 128 and RFID reader 302 are located, indicating that it is accepting the signal from those components. The SPI data line 312 is used to receive the data from the RFID reader 302 into the MCU 310, while the SPI clock line 318 synchronizes the timing of signals between the MCU 310 and the RFID readers.

If the module 136 is not the master module (step 406), the module passes the identification and location information to the master module (step 408). The master module 138 then passes the identification and information to the software layer which relays it to the database (step 410). Alternately, the MCU 310 may output the identification information through the USB 320 or Uart 322 outputs to the console server 324.

The database is updated with the server's ID and its location, e.g., the slot 104 and the rack 102 in which it resides (step 412). The module 136 may also send a signal with the server's ID to the database to indicate that a server 112 has been removed when it is taken out of the slot 104. Although not shown on the figure, many other servers or other IT components may be included in the slots on the rack or on other racks.

The foregoing description of various embodiments provides illustration and description, but is not intended to be exhaustive or to limit the invention to the precise form disclosed. Modifications and variations are possible in light of the above teachings or may be acquired from practice in accordance with the present invention. It is to be understood that the invention is intended to cover various modifications and equivalent arrangements included within the spirit and scope of the appended claims.

What is claimed is:

1. A method in a data processing system for automatically tracking locations of IT components in a data center, comprising:
inserting one or more IT components in one or more slots in one or more racks in the data center;
automatically identifying the one or more IT components in the one or more slots in the one or more racks;
automatically identifying the one or more slots in which the one or more IT components are inserted; and
automatically identifying when one or more of the IT components are removed from one or more of the slots in one or more of the racks.

2. The method of claim 1, further comprising:
automatically providing the identification of the one or more inserted IT components and the associated slot to a database; and
automatically updating the database upon receipt of the identification.

3. The method of claim 2, further comprising:
automatically providing the identification of the one or more removed IT components and the associated slot to the database; and
automatically updating the database upon receipt of the identification of the one or more removed IT components.

4. The method of claim 1, wherein each of the one or more IT components further comprise an RFID tag uniquely identifying the IT component, and wherein the method further comprises automatically identifying the one or more IT components by receiving the identification of the IT component from the associated RFID tag.

5. The method of claim 4, wherein an RFID reader performs the receiving the identification of the IT component from the associated RFID tag.

6. The method of claim 1, further comprising receiving IT component identification information from a plurality of RFID readers on a rack.

7. The method of claim 1, wherein the IT component is one of: (1) a server, (2) a router, and (3) a switch.

8. A method in a data processing system for automatically tracking locations of IT components in a data center, comprising;
inserting one or more IT components in one or more slots in a rack in the data center; and
automatically identifying the one or more IT components inserted into the one or more slots in the rack.

9. The method of claim 8, further comprising automatically sending the identification to a database.

10. The method of claim 9, further comprising automatically updating the database upon receipt of the identification.

11. A data processing system for automatically tracking locations of IT components in a data center, comprising:
a rack comprising a slot configured to store an IT component comprising an RFID tag uniquely identifying the IT component;
the slot configured to store an IT component, comprising:
an antenna configured to receive a signal from the RFID tag indicating an identification of the IT component; and
an RFID reader configured to receive the signal from the antenna, process the signal, and send the identification to a module;
the module configured to send the identification to a database; and
the database configured to store identification and location information of IT components in the data center, and to update upon receipt of the identification from the module.

12. The data processing system of claim, 11, wherein the module sends the identification to a master module configured to receive identifications from a plurality of modules.

13. The data processing system of claim 12, wherein the master module is configured to send the received identifications to the database.

14. The data processing system of claim 11, wherein the module further includes six RFID readers.

15. The data processing system of claim 14, wherein the rack further includes seven modules.

16. The data processing system of claim 11, wherein the rack comprises a plurality of slots configured to store an IT component, each slot comprising an antenna and an RP ID reader.

17. A method in a data processing system for automatically tracking locations of IT components in a data center, comprising:
inserting one or more IT components in one or more racks in the data center;
automatically identifying the one or more IT components in the one or more slots in one or more of the racks;
automatically identifying the one or more racks in which the one or more IT components are inserted; and
automatically identifying when one or more of the IT components are removed from one or more of the racks.

18. The method of claim 17, further comprising:
automatically providing the identification of the one or more inserted IT components and the associated rack to a database; and
automatically updating the database upon receipt of the identification.

19. The method of claim 18, further comprising:
automatically providing the identification of the one or more removed IT components and the associated rack to the database; and
automatically updating the database upon receipt of the identification of the one or more removed IT components.

20. The method of claim 17, wherein each of the one or more IT components further comprise an RFID tag uniquely identifying the IT component, and wherein the method further comprises automatically identifying the one or more IT components by receiving the identification of the IT component from the associated RFID tag.
